(19) United States
(12) Patent Application Publication
(10) Pub. No.: US 2014/0196936 A1
(43) Pub. Date: Jul. 17, 2014

(54) MULTILAYER CERAMIC CAPACITOR, MOUNTING BOARD THEREFOR, AND MANUFACTURING METHOD THEREOF

(71) Applicant: SAMSUNG ELECTRO-MECHANICS CO., LTD., Guynggi-do (KR)

(72) Inventors: Kyung Pyo HONG, Gyunggi-do (KR); Hyun Hee GU, Gyunggi-do (KR); Doo Young KIM, Gyunggi-do (KR); Young Ghyu AHN, Gyunggi-do (KR); Chang Hoon KIM, Gyunggi-do (KR)

(73) Assignee: SAMSUNG ELECTRO-MECHANICS CO., LTD., Gyunggi-do (KR)

(21) Appl. No.: 13/844,293

(22) Filed: Mar. 15, 2013

(30) Foreign Application Priority Data
Jan. 14, 2013 (KR) 10-2013-0003985

(51) Int. Cl. H05K 1/02; H05K 7/14

(52) U.S. Cl. CPC H05K 1/0271; H05K 7/1422
USPC 174/257; 361/301.4; 174/258; 264/619

(57) ABSTRACT

There is provided a multilayer ceramic capacitor including: a ceramic body in which a plurality of dielectric layers are stacked; a plurality of first and second internal electrodes formed on at least one surfaces of the plurality of dielectric layers and alternately exposed to both end surfaces of the ceramic body; first and second external electrodes formed on both end surfaces of the ceramic body and electrically connected to the respective first and second internal electrodes; and first and second non-conductive epoxy resin layers formed on peripheral surfaces of the first and second external electrodes except for mounting surfaces of the first and second external electrodes.

### CROSS-REFERENCE TO RELATED APPLICATIONS

This application claims the priority of Korean Patent Application No. 10-2013-0003985 filed on Jan. 14, 2013, in the Korean Intellectual Property Office, the disclosure of which is incorporated herein by reference.

### BACKGROUND OF THE INVENTION

1. Field of the Invention

The present invention relates to a multilayer ceramic capacitor, a mounting board therefor, and a manufacturing method thereof.

2. Description of the Related Art

In general, a multilayer ceramic capacitor, a multilayer chip electronic component, is a chip type condenser mounted on circuit boards of various electronic products such as display devices, including liquid crystal displays (LCDs), plasma display panels (PDPs), and the like, computers, personal digital assistants (PDAs), mobile phones, and the like, and serving to charge and discharge electricity.

Since multilayer ceramic capacitors (MLCCs) have advantages such as a relatively small size, high capacitance, ease of mounting, and the like, multilayer ceramic capacitors may be used as components in various electronic devices.

A multilayer ceramic capacitor may have a structure in which a plurality of dielectric layers and internal electrodes having different polarities and interposed between the dielectric layers, are alternately stacked.

However, since the dielectric layers have piezoelectric and electrostrictive properties, when a direct current (DC) voltage or an alternating current (AC) voltage is applied to the multilayer ceramic capacitor, a piezoelectric phenomenon may occur between the internal electrodes, and thus vibrations caused by volumetric expansion and contraction of the capacitor may be periodically generated.

Such vibrations may be transferred to a printed circuit board on which the multilayer ceramic capacitor is mounted through external electrodes of the multilayer ceramic capacitor and a solder connecting the external electrodes to the printed circuit board, such that the entire printed circuit board may become an acoustic reflection surface to transmit the sound of vibrations as noise.

In this case, since the solder connecting the external electrodes to the printed circuit board is inclined with respect to surfaces of the external electrodes formed on both ends of the multilayer ceramic capacitor at a predetermined height, the vibrations of the multilayer ceramic capacitor may be easily transferred to the printed circuit board, such that the generation of noise from the vibrations may be increased.

Vibration noise may have a frequency corresponding to an audio frequency within a range of 20 to 20000 Hz, potentially causing listener discomfort. The vibration noise causing listener discomfort, as described above, is known as acoustic noise. Research into technology for decreasing such acoustic noise has been demanded.

A multilayer ceramic capacitor and a mounting board therefor are disclosed in the following Patent Document 1, but a structure in which non-conductive epoxy resin layers are formed on peripheral surfaces of external electrodes is not disclosed therein.

### RELATED ART DOCUMENT

(Patent Document 1) Korean Patent No. 10-1058697

### SUMMARY OF THE INVENTION

An aspect of the present invention provides a multilayer ceramic capacitor capable of effectively decreasing noise generated in the case that vibrations caused by a piezoelectric phenomenon are transferred to a printed circuit board through external electrodes of the multi-layer ceramic capacitor and a solder.

According to an aspect of the present invention, there is provided a multilayer ceramic capacitor including: a ceramic body in which a plurality of dielectric layers are stacked; a plurality of first and second internal electrodes formed on at least one surfaces of the plurality of dielectric layers and alternately exposed to both end surfaces of the ceramic body; first and second external electrodes formed on both end surfaces of the ceramic body and electrically connected to the respective first and second internal electrodes; and first and second non-conductive epoxy resin layers formed on peripheral surfaces of the first and second external electrodes except for mounting surfaces of the first and second external electrodes.

The first and second non-conductive epoxy resin layers may have a height equal to 20% or greater of a height of the ceramic body.

The multilayer ceramic capacitor may further include first and second plating layers formed on surfaces of the first and second external electrodes to be interposed between the first and second external electrodes and the first and second non-conductive epoxy resin layers.

The first and second plating layers may include a nickel (Ni) plating layer formed on the surfaces of the first and second external electrodes and a tin (Sn) plating layer formed on a surface of the nickel (Ni) plating layer.

According to another aspect of the present invention, there is provided a mounting board for a multilayer ceramic capacitor, the mounting board including: a printed circuit board having first and second electrode pads formed thereon; and a multilayer ceramic capacitor installed on the printed circuit board, wherein the multilayer ceramic capacitor includes a ceramic body in which a plurality of dielectric layers are stacked; a plurality of first and second internal electrodes formed on at least one surfaces of the plurality of dielectric layers and alternately exposed to both end surfaces of the ceramic body; first and second external electrodes formed on both end surfaces of the ceramic body, electrically connected to the respective first and second internal electrodes, and having lower surfaces connected to the first and second electrode pads by solder; and first and second non-conductive epoxy resin layers formed on peripheral surfaces of the first and second external electrodes except for mounting surfaces of the first and second external electrodes to allow the solder not to be formed thereon.

According to another aspect of the present invention, there is provided a manufacturing method of a multilayer ceramic capacitor, the manufacturing method including: preparing a plurality of ceramic sheets; forming first and second internal electrodes on at least one surfaces of the plurality of ceramic sheets; stacking the plurality of ceramic sheets on which the first and second internal electrodes are formed to form a stack; cutting the stack while allowing one ends of the first and second internal electrodes to be alternately exposed to both end surfaces of the stack, respectively; sintering the cut stack to form a ceramic body having the plurality of first and second internal electrodes; forming first and second external electrodes, using a conductive paste, on both end surfaces of the ceramic body to be electrically connected to exposed portions of first and second internal electrodes, respectively; and applying a non-conductive epoxy resin to peripheral surfaces of the first and second external electrodes except for mounting surfaces of the first and second external electrodes to form first and second non-conductive epoxy resin layers.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a multilayer ceramic capacitor according to an embodiment of the present invention;

FIG. 2 is a cross-sectional view taken along line A-A′ of FIG. 1;

FIG. 3 is a longitudinal cross-sectional view schematically showing a state in which the multilayer ceramic capacitor of FIG. 2 is mounted on a printed circuit board;

FIGS. 4A and 4B are photographs showing one surface of a mounting board for a multilayer ceramic capacitor according to the related art;

FIGS. 5A and 5B are photographs showing one surface of a mounting board for the multilayer ceramic capacitor according to the embodiment of the present invention; and

FIG. 6 is a graph showing a comparison result of acoustic noise between the multilayer ceramic capacitor according to the related art and the multilayer ceramic capacitor according to the embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

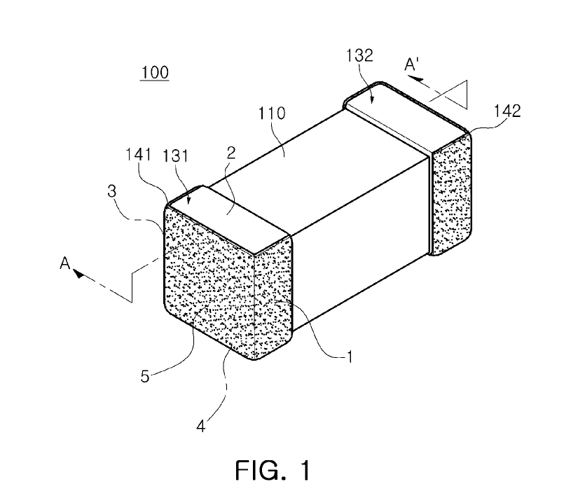

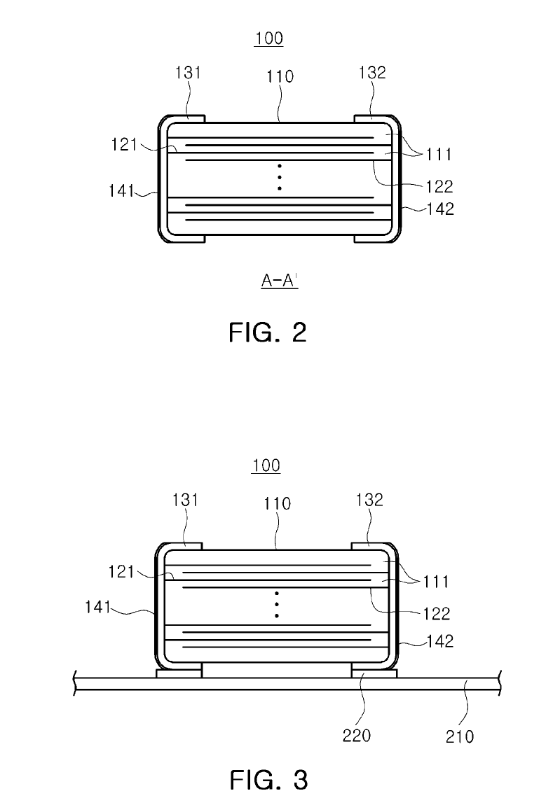

Referring to FIGS. 1 and 2, a multilayer ceramic capacitor 100 according to the embodiment of the present invention may include a ceramic body 110 in which a plurality of dielectric layers 111 are stacked, a plurality of first and second internal electrodes 121 and 122 formed on at least one surfaces of the dielectric layers 111, first and second external electrodes 131 and 132 formed on both end surfaces of the ceramic body 110 and electrically connected to the first and second internal electrodes 121 and 122, respectively, and first and second non-conductive epoxy resin layers 141 and 142 formed on peripheral surfaces of the first and second external electrodes 131 and 132, except for mounting surfaces for the first and second external electrodes 131 and 132.

The ceramic body 110 may be formed by stacking the plurality of ceramic dielectric layers 111 and then sintering the same, wherein the dielectric layers 111 may be integrated such that boundaries between adjacent dielectric layers 111 may not be readily apparent.

This ceramic body 110 may have a rectangular parallelepiped shape in general, but the present invention is not limited thereto. Furthermore, a size of the ceramic body 110 is not particularly limited. For example, the ceramic body 110 may have a size of 0.6 mm×0.3 mm, or the like, thereby configuring a multilayer ceramic capacitor having high capacitance. In addition, cover parts formed of dielectric layers (not shown) having a predetermined thickness may be further provided to form uppermost and lowermost portions of the ceramic body 110, as needed.

The dielectric layers 111 contribute to the formation of capacitance in the capacitor, wherein a thickness of a single dielectric layer may optionally be changed, according to a desired amount of capacitance to be formed within the multilayer ceramic capacitor 100. The thickness of the single dielectric layer may be 0.1 to 1.0 μm after sintering, but the present invention is not limited thereto.

In addition, the dielectric layers 111 may contain a ceramic material having a high degree of permittivity, for example, a BaTiO₃ based ceramic powder, or the like, but the present invention is not limited thereto.

In the BaTiO₃-based ceramic powder, (Ba₁₋ₓCaₓ) TiO₃, Ba (Ti_{1-y}Ca_{y})O₃, (Ba₁₋ₓCaₓ) (Ti_{1-y}Zr_{y})O₃, or Ba(Ti_{1-y}Zr_{y})O₃ in which Ca, Zr, or the like, partially dissolved in BaTiO₃, may be used, but the BaTiO₃-based ceramic powder is not limited thereto.

Meanwhile, the dielectric layers 111 may further contain various ceramic additives such as transition metal oxides or carbides, a rare earth element, magnesium (Mg), aluminum (Al), or the like, an organic solvent, a plasticizer, a binder and a dispersant, or the like, as well as the ceramic powder.

After the first and second internal electrodes 121 and 122 may be formed on ceramic sheets forming the dielectric layers 111 and stacked, the first and second internal electrodes 121 and 122 may be formed in the ceramic body 110 by sintering, having one dielectric layer 111 interposed therebetween.

The first and second internal electrodes 121 and 122 as described above, a pair of electrodes having opposite polarities, may be disposed to face each other in a direction in which the dielectric layers 111 are stacked, and may be electrically insulated from each other by the dielectric layer 111 interposed therebetween.

In addition, one ends of the first and second internal electrodes 121 and 122 may be exposed to both end surfaces of the ceramic body 110, respectively. One ends of the first and second internal electrodes 121 and 122 alternately exposed to both end surfaces of the ceramic body 110 as described above may be electrically connected to the first and second external electrodes 131 and 132, respectively.

The first and second internal electrodes 121 and 122 may be formed of a conductive metal, for example, nickel, a nickel alloy, or the like, but the present invention is not limited thereto.

Therefore, when voltage is applied to the first and second external electrodes 131 and 132, electric charges are accumulated between the first and second internal electrodes 121 and 122 facing each other. In this case, the capacitance of the multilayer ceramic capacitor 100 may be in proportion to an overlap area of the first and second internal electrodes 121 and 122 in the direction in which the dielectric layers 111 are stacked.

The first and second external electrodes 131 and 132 may be formed by sintering a conductive paste for external electrodes containing copper (Cu) in order to provide a high degree of reliability through excellent heat cycle resistance, moisture resistance, and the like, while having excellent electrical properties, but the present invention is not limited thereto.

The first and second non-conductive epoxy resin layers 141 and 142 are provided to allow a solder not to be formed on the peripheral surfaces of the first and second external electrodes 131 and 132 except for the mounting surface when the capacitor is mounted on the printed circuit board.

In the present embodiment, the first and second external electrodes 131 and 132 may be formed to include first to fifth surfaces 1 to 5 so as to cover both end surfaces of the ceramic body 110. In the present embodiment, the non-conductive epoxy resin layers 141 and 142 are formed on the first, third, and fifth surfaces 1, 3, and 5, of the first and second external electrodes 131 and 132 but not formed on the second and fourth surfaces 2 and 4 of the first and second external electrodes 131 and 132.

That is, the first and second non-conductive epoxy resin layers 141 and 142 may be substantially formed to have a “[” shape on the peripheral surfaces of the first and second external electrodes 131 and 132, but the shape of the first and second non-conductive epoxy resin layers 141 and 142 according to the embodiment of the present invention is not limited thereto. For example, the first and second non-conductive epoxy resin layers 141 and 142 may be formed on the fourth surface 4, the mounting surface of the first and second external electrodes 131 and 132, and the second surface 2, an upper surface facing the fourth surface 4, as needed.

Further, a height of the first and second non-conductive epoxy resin layers 141 and 142 may be equal to 20% or greater of that of a chip, in consideration of a general height of a solder, but the present invention is not limited thereto.

Meanwhile, first and second plating layers (not shown) may further be formed on the surfaces of the first and second external electrodes 131 and 132 to be interposed between the first and second external electrodes 131 and 132 and the first and second non-conductive epoxy resin layers 141 and 142.

The first and second plating layers are provided to increase adhesion strength at the time of soldering and mounting the capacitor on the board, or the like. The plating is performed by the method known in the art, and lead-free plating may be preferable, but the present invention is not limited thereto.

In addition, the first and second plating layers may include a pair of nickel (Ni) plating layers (not shown) formed on outer surfaces of the first and second external electrodes 131 and 132 and a pair of tin (Sn) layers (not shown) formed on outer surfaces of the nickel (Ni) plating layers.

FIG. 3 is a longitudinal cross-sectional view schematically showing a mounting board for the multilayer ceramic capacitor according to the embodiment of the present invention.

Referring to FIG. 3, a mounting board for the multilayer ceramic capacitor 100 according to the embodiment of the present invention may include a printed circuit board 210 on which the multilayer ceramic capacitor 100 is mounted and first and second electrode pads (not shown) formed on the printed circuit board 210 to be spaced apart from each other.

In this case, the multilayer ceramic capacitor 100 may be electrically connected to the printed circuit board 210 by a solder 220 in a state in which the fourth surfaces 4 of the first and second external electrodes 131 and 132 on which the non-conductive epoxy resin layers 141 and 142 are not formed are positioned to contact the first and second electrode pads of the printed circuit board 210. When voltage is applied in a state in which the multilayer ceramic capacitor 100 is mounted on the printed circuit board 210 as described above, acoustic noise may be generated.

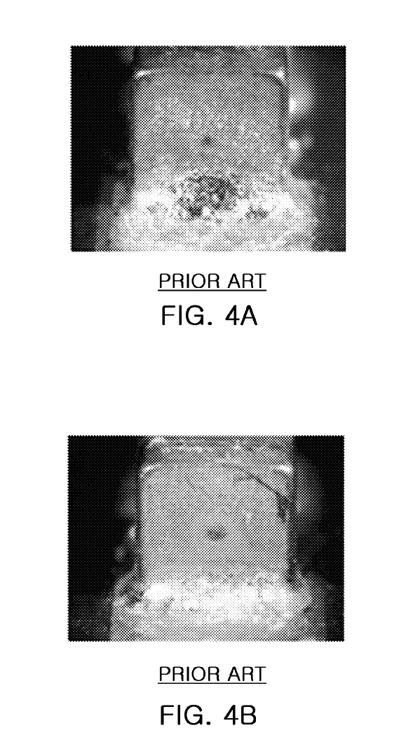

FIGS. 4A and 4B are photographs showing one surface of a mounting board for a multilayer ceramic capacitor according to the related art. Referring to FIGS. 4A and 4B, in the multilayer ceramic capacitor according to the related art, it may be confirmed that solder is partially formed on first, third, and fifth surfaces of external electrodes of the multilayer ceramic capacitor.

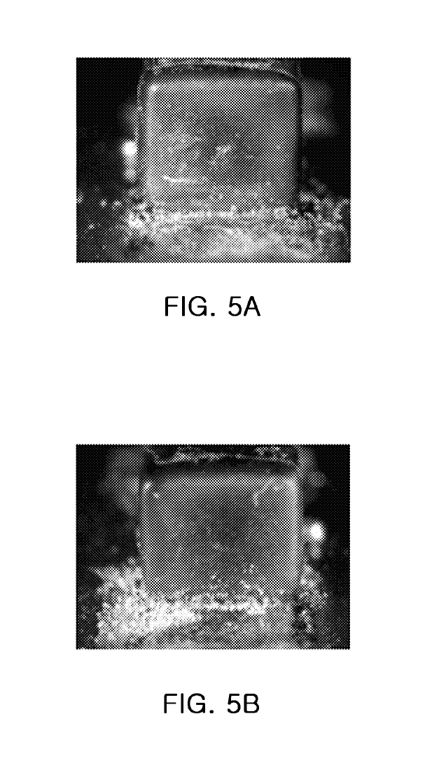

FIGS. 5A and 5B are photographs showing one surface of a mounting board for the multilayer ceramic capacitor according to the embodiment of the present invention. Referring to FIGS. 5A and 5B, according to the embodiment of the present invention, since the first and second non-conductive epoxy resin layers 141 and 142 are formed on the first, third, and fifth surfaces 1, 3, and 5 of the first and second external electrodes 131 and 132, the solder 220 is not formed on the first, third, and fifth surfaces 1, 3, and 5, unlike the multilayer ceramic capacitor according to the related art, such that the solder 220 is only formed on the fourth surfaces 4 of the first and second external electrodes 131 and 132 and around the fourth surface 4 at a minimum height.

When voltages having different polarities are applied to the first and second external electrodes 131 and 132 formed on both end portions of the multilayer ceramic capacitor 100 in a state in which the multilayer ceramic capacitor 100 is mounted on the printed circuit board 210, the ceramic body 110 may be expanded and contracted in a thickness direction by an inverse piezoelectric effect of the dielectric layer 111, and both end portions of the first and second external electrodes 131 and 132 may be contracted and expanded as opposed to expansion and contraction of the ceramic body 110 in the thickness direction by the Poisson effect.

Here, a central portion of the multilayer ceramic capacitor 100, a maximally expanded portion based on both end portions of the first and second external electrodes 131 and 132 in a length direction, may be a cause of acoustic noise generation.

However, in the mounting board for the multilayer ceramic capacitor 100 according to the embodiment of the present invention, the height of the solder 220 is significantly decreased, such that vibrations transferred by the maximally expanded central portion of the multi-layer ceramic capacitor 100 may be decreased, whereby acoustic noise may also be reduced.

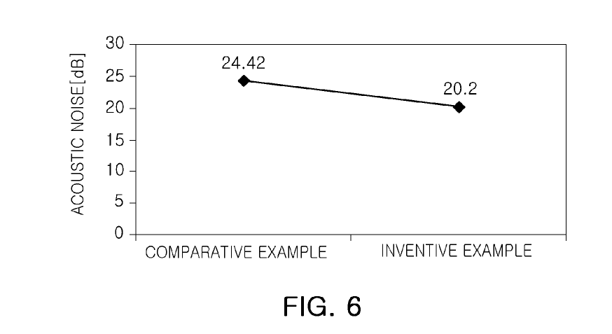

That is, referring to FIG. 6, in the Comparative Example in which the non-conductive epoxy resin layers were not formed, acoustic noise was 24.42 dB, while in the Inventive Example in which the non-conductive epoxy resin layers were formed, acoustic noise was 20.2 dB. Therefore, it may be confirmed that acoustic noise in the Inventive Example was significantly decreased by an amount about 17% or more than that in the Comparative Example.

Hereinafter, a manufacturing method for a multilayer ceramic capacitor according to the embodiment of the present invention will be described.

First, a plurality of ceramic sheets may be prepared. The ceramic sheets, provided to form dielectric layers 111 of a ceramic body 110, may be manufactured by mixing ceramic powder, a polymer, and a solvent, to prepare a slurry, and forming the prepared slurry into sheets having a thickness of several μm with a doctor blade method, or the like.

Next, first and second internal electrodes 121 and 122 may be formed by printing a conductive paste on at least one surfaces of the ceramic sheets to have a predetermined thickness. In this case, the first and second internal electrodes 121 and 122 may be exposed to both end surfaces of the ceramic sheets, respectively. In addition, as a printing method of the conductive paste, a screen printing method, a gravure printing method, or the like, may be used, but the present invention is not limited thereto.

Then, the plurality of ceramic sheets on which the first and second internal electrodes 121 and 122 are formed may be alternately stacked and pressed in a stacking direction, such that the plurality of ceramic sheets and the first and second internal electrodes 121 and 122 formed on the ceramic sheets are compressed to form a stack.

Next, the stack may be cut as a chip along boundaries corresponding to one capacitor while allowing one ends of the first and second internal electrodes 121 and 122 to be alternately exposed to both end surfaces of the stack, respectively.

Next, the cut chip may be sintered at a high temperature, such that a ceramic body 110 having the plurality of first and second internal electrodes 121 and 122 may be obtained.

Then, first and second external electrodes 131 and 132 may be formed on both end surfaces of the ceramic body 110. The first and second external electrodes 131 and 132 may be formed of a conductive paste containing copper (Cu), or the like, so as to be electrically connected to the respective first and second internal electrodes 121 and 122, while covering exposed portions of the first and second internal electrodes 121 and 122.

In this case, plating may be performed on surfaces of the first and second external electrodes 131 and 132, as needed. As a material used in the plating, nickel, tin, a nickel-tin alloy, or the like, may be used, and a nickel plating layer and a tin plating layer may be sequentially formed on the surfaces of the first and second external electrodes 131 and 132.

Next, non-conductive epoxy resin may be applied to peripheral surfaces of the first and second external electrodes 131 and 132 or surfaces of the plating layers except for a mounting surface and dried, thereby forming first and second non-conductive epoxy resin layers 141 and 142.

As set forth above, according to embodiments of the present invention, non-conductive epoxy resin layers are formed on peripheral surfaces of external electrodes except for mounting surfaces of external electrodes to thereby decrease a height of solder formed on the peripheral surfaces of the external electrodes, such that the transferring of vibrations generated by a multilayer ceramic capacitor to a printed circuit board may be decreased, whereby acoustic noise can be reduced.

While the present invention has been shown and described in connection with the embodiments, it will be apparent to those skilled in the art that modifications and variations can be made without departing from the spirit and scope of the invention as defined by the appended claims.

What is claimed is:

1. A multilayer ceramic capacitor comprising:
a ceramic body in which a plurality of dielectric layers are stacked;
a plurality of first and second internal electrodes formed on at least one surfaces of the plurality of dielectric layers and alternately exposed to both end surfaces of the ceramic body;
first and second external electrodes formed on both end surfaces of the ceramic body and electrically connected to the respective first and second internal electrodes; and
first and second non-conductive epoxy resin layers formed on peripheral surfaces of the first and second external electrodes except for mounting surfaces of the first and second external electrodes.

2. The multilayer ceramic capacitor of claim 1, wherein the first and second non-conductive epoxy resin layers have a height equal to 20% or greater of a height of the ceramic body.

3. The multilayer ceramic capacitor of claim 1, further comprising first and second plating layers formed on surfaces of the first and second external electrodes to be interposed between the first and second external electrodes and the first and second non-conductive epoxy resin layers.

4. The multilayer ceramic capacitor of claim 3, wherein the first and second plating layers include a nickel (Ni) plating layer formed on the surfaces of the first and second external electrodes and a tin (Sn) plating layer formed on a surface of the nickel (Ni) plating layer.

5. Amounting board for a multilayer ceramic capacitor, the mounting board comprising:
a printed circuit board having first and second electrode pads formed thereon; and
a multilayer ceramic capacitor installed on the printed circuit board,
wherein the multilayer ceramic capacitor includes:
a ceramic body in which a plurality of dielectric layers are stacked;
a plurality of first and second internal electrodes formed on at least one surfaces of the plurality of dielectric layers and alternately exposed to both end surfaces of the ceramic body;
first and second external electrodes formed on both end surfaces of the ceramic body, electrically connected to the respective first and second internal electrodes, and having lower surfaces connected to the first and second electrode pads by solder; and
first and second non-conductive epoxy resin layers formed on peripheral surfaces of the first and second external electrodes except for mounting surfaces of the first and second external electrodes to allow the solder not to be formed thereon.

6. The mounting board of claim 5, wherein the first and second non-conductive epoxy resin layers have a height equal to 20% or greater of a height of the ceramic body.

7. The mounting board of claim 5, wherein the multilayer ceramic capacitor further includes first and second plating layers formed on surfaces of first and second external electrodes to be interposed between the first and second external electrodes and the first and second non-conductive epoxy resin layers.

8. The mounting board of claim 7, wherein the first and second plating layers include a nickel (Ni) plating layer formed on the surfaces of the first and second external electrodes and a tin (Sn) plating layer formed on a surface of the nickel (Ni) plating layer.

9. A manufacturing method of a multilayer ceramic capacitor, the manufacturing method comprising:
preparing a plurality of ceramic sheets;
forming first and second internal electrodes on at least one surfaces of the plurality of ceramic sheets;
stacking the plurality of ceramic sheets on which the first and second internal electrodes are formed to form a stack;
cutting the stack while allowing one ends of the first and second internal electrodes to be alternately exposed to both end surfaces of the stack, respectively;
sintering the cut stack to form a ceramic body having the plurality of first and second internal electrodes;
forming first and second external electrodes, using a conductive paste, on both end surfaces of the ceramic body to be electrically connected to exposed portions of first and second internal electrodes, respectively; and
applying a non-conductive epoxy resin to peripheral surfaces of the first and second external electrodes except for mounting surfaces of the first and second external electrodes to form first and second non-conductive epoxy resin layers.

10. The manufacturing method of claim 9, wherein the first and second non-conductive epoxy resin layers are formed to have a height equal to 20% or greater of a height of the ceramic body.

11. The manufacturing method of claim 9, further comprising forming first and second plating layers on surfaces of the first and second external electrodes prior to the forming of the first and second non-conductive epoxy resin layers.

12. The manufacturing method of claim 11, wherein, in the forming of the first and second plating layers, a nickel (Ni) plating layer is formed on the surfaces of the first and second external electrodes, and a tin (Sn) plating layer is formed on a surface of the nickel (Ni) plating layer.
